(19) United States
(12) Patent Application Publication
(10) Pub. No.: US 2015/0078584 A1
(43) Pub. Date: Mar. 19, 2015

(54) Live Sound Mixer User Interface

(71) Applicant: Nancy Diane Moon, Del Mar, CA (US)

(72) Inventor: Nancy Diane Moon, Del Mar, CA (US)

(21) Appl. No.: 14/027,350

(22) Filed: Sep. 16, 2013

(51) Int. Cl. G10H 1/46; H03G 3/02

(52) U.S. Cl. CPC G10H 1/46; H03G 3/02
USPC 381/104

(57) ABSTRACT

Exemplary embodiments are directed to an apparatus and method for a user interface of an audio mixer intended for live performance situations where the musician can quickly and easily manipulate a plurality of audio levels and complex sound effects parameters. The user interface is comprised of a hierarchical control interaction that reduces the number of physical controls on the panel while also reducing the number of user interactions required to adjust a parameter. The user interface lends itself to remote control of an audio mixer via a four-wire digital interface.

### BACKGROUND OF THE INVENTION

Live music is an important and exciting aspect of every culture. Even to people used to hearing recorded music at every turn, a sign for live music on a restaurant, coffeehouse or bar is still a powerful attraction. What people have come to expect is carefully produced and mixed live music with all the clarity of a recording. The instruments should not over power the vocals and the overall effect should be balanced.

To achieve this balance, almost every live sound situation calls for the use of a device called a mixer. A mixer takes sound-signal inputs from instruments and microphones and adjusts the volume, tone and a myriad of effects for each sound source. Often the mixer takes the form of the familiar mixing board, full of closely spaced knobs, sliders, switches and meters, requiring a sound engineer to focus on making the necessary adjustments.

For a small band or individual player where a dedicated sound engineer is not appropriate, use of a mixing board is a distraction and a difficulty. Similarly, for a keyboard player with multiple instruments, using a mixing board as a submixer to combine several instruments into one send to the main mixer is difficult to manage while playing.

A recent development in this field is mixers that are controlled by the touch screen of a tablet computer. The sliders and knobs appear on the screen and a finger on the touch screen manipulates the controls. In many ways this is a step in the wrong direction as the player cannot adjust a control by feel, but must use careful hand-eye coordination on the touch screen, distracting from playing the instrument.

A need exists for a sound mixer with a user interface that is simple to operate and requires a minimum of visual attention for the most common adjustments, and where complex, sound-effects menus are immediately available adjustments that may be easily accessed by the player.

### BRIEF SUMMARY OF THE INVENTION

It is, therefore, the object of the present invention to improve the user interface of an audio mixer to make it more suitable for use by players during live performance by providing a minimum number of simple-to-operate controls arranged in a hierarchical relationship while providing quick and intuitive access to control over an adequate number of audio channels and complex sound effects parameters.

Control over volume levels and other parameters is accomplished with a single type of control that combines rotation for adjustment with a key switch for interaction with the next lower tier in the hierarchy, plus a display that provides visual feedback of selections and settings. In one embodiment, the control will be a rotary encoder with integrated key switch, a commonly available, inexpensive and easy-to-understand control device. The number of controls dedicated to volume-level adjustment is limited to the number that can be easily negotiated by feel with one hand, such as four, channel-volume controls and one master, output-volume control, which can control eight, twelve or more audio channels. Similarly, the number of controls dedicated to the sound-effects menus is limited but the menu structure is flat with few user inputs required to adjust any parameter. The audio-channel controls, via the hierarchical interaction, preselect which sound-effect menu items to activate and display.

### BRIEF DESCRIPTION OF DRAWINGS

FIG. 1—shows connections for a keyboard-player rig using a mixing board.

FIG. 2—shows the controls on a simple 8-channel mixing board.

FIG. 3—shows the details of a channel-strip portion of a mixing board.

FIG. 4—shows a typical mini-mixer control panel.

FIG. 5—depicts connections for a keyboard-player rig with a remotely-controlled mixer utilizing the user interface of the present invention.

FIG. 6—depicts the control panel for the remote-mixer controller.

FIG. 7—depicts one visual VU meter/volume control indicator from the screen of the remote-mixer controller.

FIG. 8—depicts one screen display of the remote-mixer controller with the lower bank active.

FIG. 9—depicts one screen display of the remote-mixer controller with the upper bank active.

FIG. 10—depicts the menu portion of the remote-mixer controller screen.

FIG. 11—is a schematic of the control interactions of the remote-mixer controller.

FIG. 12—is a schematic of the audio path of the remote mixer.

FIG. 13—depicts the four-wire controller interface for the remote-mixer controller.

### DETAILED DESCRIPTION OF THE INVENTION

The mixer and user interface described herein were developed as part of the electronically-orbited speaker disclosed in patent applications US2013/0163787, Electronically Orbited Speaker System, and US2014/024644, Apparatus and Method for a Celeste in an Electronically-Orbited Speaker, which are incorporated in their entirety herein. While this user interface has particular value to the electronically-orbited speaker system, the advantages are applicable to other audio-mixer products.

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance or illustration” and should not necessarily be construed as preferred or advantageous over other exemplary embodiments.

This detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block-diagram form in order to avoid obscuring the novelty of the exemplary embodiments presented herein.

In particular, the exemplary embodiment is described in terms of an audio mixer with two monaural inputs and six stereo inputs; a total of eight, audio channels that may be controlled. The number and type of audio channels may be any number appropriate for the intended use of the audio mixer. The exemplary embodiment is described as being comprised of one Master control, four, channel-volume controls and three, menu controls; but the number and configuration of controls may vary over a range while being consistent with the present invention. The exemplary embodiment is described in terms of a single, color-display screen; though the user feedback may be delivered by any device or devices that provide visual feedback to the user.

The term “control”, when used as a noun, is used herein to mean a device or collection of devices that sense a motion by the user and convert that sense into an adjustment of a parameter. A control may include sensing a rotation or linear movement and covert that sense into an adjustment of a parameter with a plurality of values. A control may also include sensing a depression and convert that sense into a momentary switching action.

The term “rotary encoder” is used herein to mean a device that senses a rotary motion and produces a series of electrical signals that may be interpreted by other circuits to be an increase or a decrease of a parameter value. A rotary encoder may be of an optical or mechanical type. For simplicity of description, rotary encoder will include devices that sense a linear motion by the user and produce similar electrical signals.

The term “key switch” is used herein to mean a part of a control that senses a depression, as in the depression of a key on a keyboard. A key switch produces a momentary switching action.

The term “toggle” is used herein to mean switching between two states by repeated activation of a momentary switch. Each activation changes to the alternate state. The term toggle may be extended to mean switching between more than two states.

The term “radio button” is used herein to mean a switching function where two or more momentary switches are used to switch between a plurality of states. Activating a switch changes the state to the state or states associated with that switch. Activating a switch where the state is already one of the states associated with that switch makes no change.

The term “modulo increment” is used herein to mean a switching function where one momentary switch is used to select between three or more states. Each activation of the momentary switch increments the state to the next state in order. When the last state is reached, the next activation returns the state to the initial state.

The terms “audio-level control” and “volume control” are used herein interchangeably to mean a control function that adjusts the gain in an audio path in order to achieve a desired output signal strength.

The term “VU meter” is used herein to mean a visual indication of a measured audio signal strength.

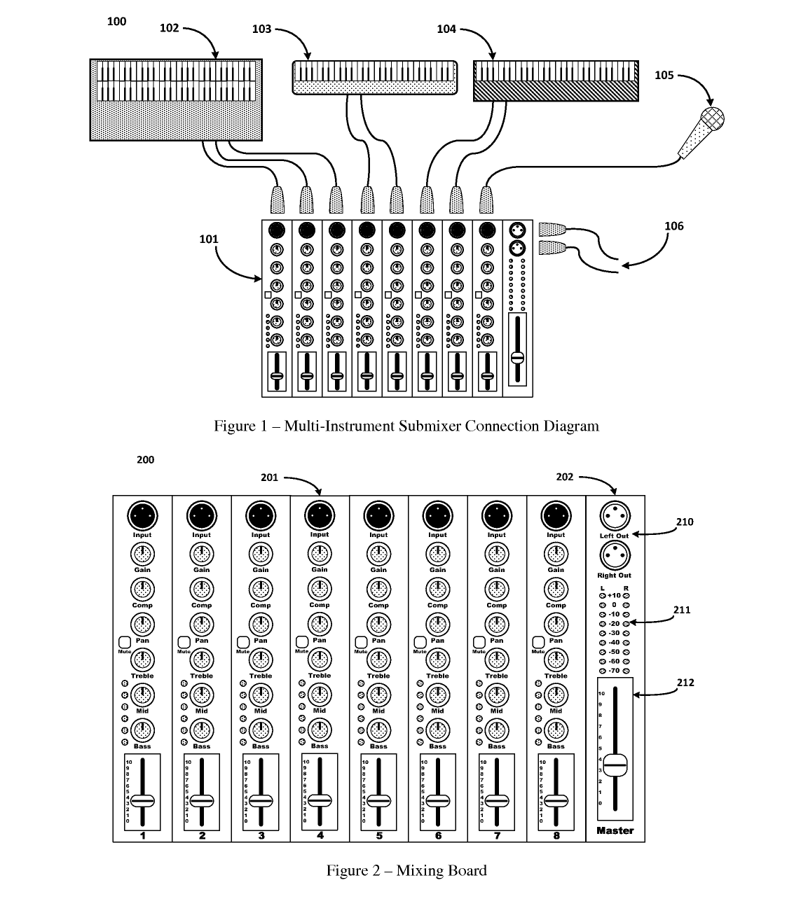

FIG. 1 depicts an exemplary connection diagram 100 for a keyboard player in a live-performance band. The play uses three keyboard instruments in this example, a combo organ 102, an electronic, music synthesizer 103 and an electronic, stage piano 104. For live-music performance it is not uncommon for a musician to use several more instruments than shown here. In addition, the player has a vocal microphone 105.

Keyboard instruments often have multiple outputs. To avoid having many audio cables running from the player's performance position to the main mixing console, it is common practice to use a submixer 101 to combine audio signals. This also gives the keyboard player control over the relative audio levels of the instruments and reduces many long runs of cable to the main mixing console.

The number of audio signals multiplies quickly as new instruments are added to a rig. Most electronic, music synthesizers 103 and electronic, stage pianos 104 have two, audio-signal outputs for left and right stereo. Many combo organs 102 have the stereo pair of outputs plus a separate, audio-signal output intended for special organ effects, such as an orbital or rotary speaker. The three exemplary instruments 102, 103, 104 plus the vocal microphone 105 occupy all eight inputs of an exemplary eight channel submixer 101. Musicians often must resort to using 16- or 24-channel mixing boards to have an adequate number of music-signal inputs for the submixer 101.

Most audio mixers on the market are modeled after the mixing boards used in recording studios where maximum flexibility is required. FIG. 2 depicts an exemplary mixing board 200 of the type popularly used by musicians. It consists of eight, channel strips 201, one for each input, and a single, output section 202. The output section 202 includes a pair of output connectors 210 for the left- and right-audio signal sends to the master mixing console. The audio levels are indicated by the LED VU meters 211 and the output level is adjusted by the master, level control 212. A left-summing bus and a right-summing bus collect the audio signals from the channel strips and feed the left and right signals to the output section 202.

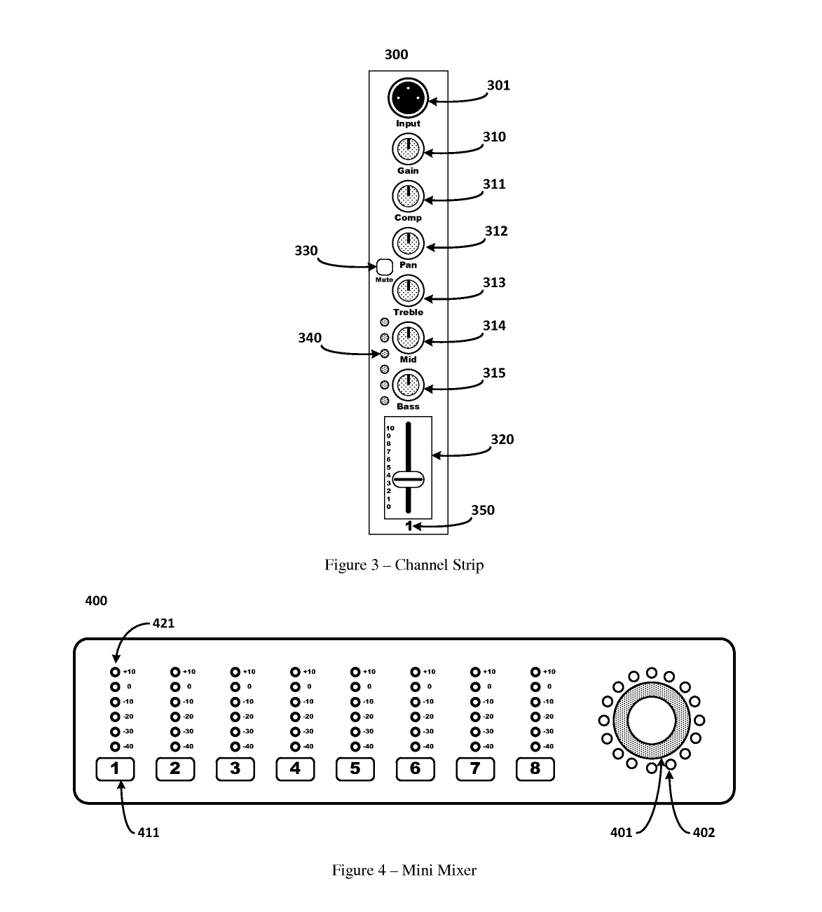

An exemplary channel strip 300 is shown in FIG. 3. Only one channel strip of the eight of mixing board 200 is shown for clarity. An audio signal from an instrument or other sound source is plugged into the jack 301 at the top of the strip. Some mixers have the connector mounted on the back of the console. The input jack 301 is often an XLR connector, sometimes a TRS jack and in recent products, a combination jack that can receive either XLR or TRS plugs. Audio gain of the preamplifier is adjusted with the Gain control 310. Compression is adjusted with the Comp control 311 to reduce audio peaks that may cause distortion further along in the signal path. The Pan control 312 adjusts the level of signal from this channel strip 300 that is fed to the left- or right-summing bus. The Treble control 313, Mid control 314 and Bass control 315 adjust the frequency response of the audio signal. The signal level of this channel is indicated by the LED VU meter 340. The Mute button 330 turns off the signal without disturbing the other level controls. The level control 320 makes use of a linear potentiometer to allow adjustment of the audio-signal level while providing a visual feedback of the setting. The channel number 350 notes which channel the channel strip 300 controls. As the number of channel strips increases, keeping track of which channel strip controls which signal becomes more difficult.

Not shown here are the further controls and indicators often built into modern mixing boards which have built-in sound effects. These effects include flanger, reverberation, rotary speaker simulator and so on. These effects are often controlled with one knob and a few buttons that require a deep and complex menu structure to assign the effects to particular channels and adjust the parameters of the effects.

While the flexibility of the traditional mixing board 200 is welcomed by dedicated audio engineer who can focus on just the mixing board, the complexity of this flexibility quickly becomes a detriment to a musician who is trying to play in a live situation simultaneously with making adjustments to the submixer 101. In this simple example there are 65 separate knobs and switches and ten level meters to monitor. To complicate matters, audio signals from each instrument are often split between two or more channel strips, necessitating adjustment of multiple controls to set the level on one instrument. It is very difficult to navigate this thicket of controls and indicators while carrying on a tune. Between songs on a dark stage, the complex user interface is still difficult when both hands and both eyes are free to focus on the mixing adjustments. Another drawback of the standard mixing board is that many thick audio cables must be brought to the playing position, making a mess of an already crowded space.

An alternative to the full-featured mixing board is the mini mixer 400 shown in FIG. 4. Instead of an individual control for each function, this solution goes to the opposite extreme of a single control for all functions. The rotary encoder 401 is used to adjust the audio level of each of the eight channels. A separate button 411 for each channel is used to select the channel to be adjusted. If channel b 1 button 411 were depressed, the button would light up indicating the selected channel. The level setting for that channel would be indicated by the ring of LEDs 402 surrounding the rotary encoder 401. Turning the rotary encoder 401 would change the channel 1 level setting and the indication by the LEDs. Pressing one of the other channel buttons would access the level-setting indication and level adjustment for that channel. The audio-level measurement for each channel is continuously available on the LEDs 421 above each channel button.

While the mini mixer 400 is simpler, more compact and less expensive than the mixing board 200, the mini mixer 400 lacks flexibility and many of the needed features desired by musicians. What is needed is a mixer designed for the active player with a simple user interface but rapid access to the desired features. It is highly desired that the user interface be simple enough to make frequent adjustments by feel alone so that the player may continue playing with minimum distraction. It is also desirable to keep the mass of audio cables away from the playing position. The mixer and user interface described hereon meets these needs.

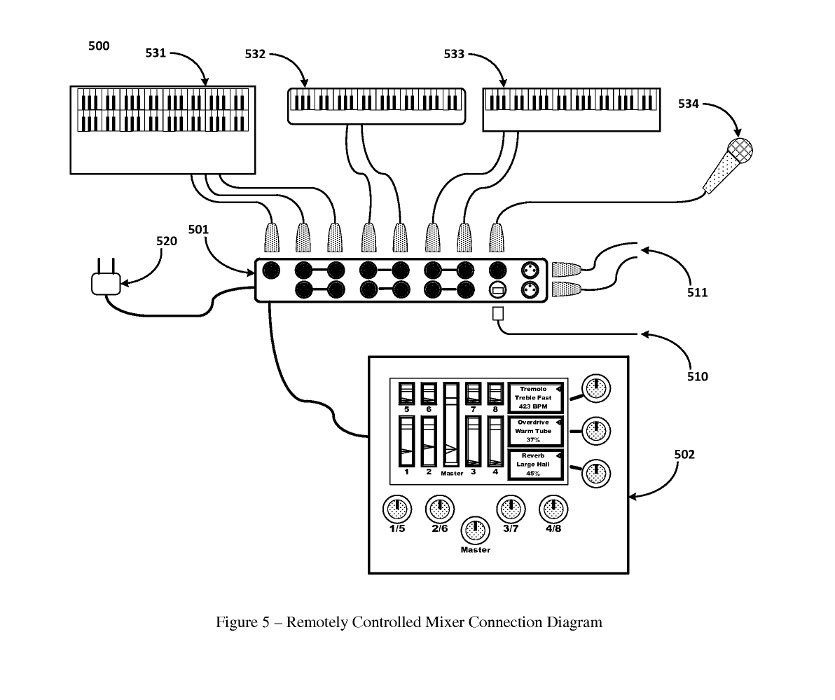

The exemplary advantageous equipment configuration of the present invention is illustrated in FIG. 5. The input module 501 is comprised of the audio input and output connectors, the signal processing circuits, power supply and a single interface connector for the cable that runs to the controller 502. The input module 501 is intended to be placed in an out-of-the-way location while the controller 502 is intended to be placed near the player. This keeps the audio cables away from the playing position.

The inputs to the input module 501 consist of a single monaural input for a special signal-processing channel generally used for an organ. A second monaural input is intended for a vocal microphone or a monaural instrument. Six stereo pairs make up the remaining inputs for a total of eight channels. It would require a mixing board of at least 14 channels to provide the same number of inputs. While stereo channels are sometimes seen on low-cost mixers, having the majority of the channels be dedicated to stereo instruments is not available.

Using the example from FIG. 1 three keyboard instruments and one vocal microphone are connected to the mixer. Combo organ 531 has a stereo pair of outputs, which connect to a stereo pair of inputs at the input module 501. In addition, the combo organ 531 has a rotary-channel output that is connected to the special signal-processing monaural input at the input module 501. This special, signal-processing input may be implemented as an XLR jack, TS or TRS jack, 8-pin DIN connector, 11-pin circular connector, or any other type connector appropriate for an instrument or sound source. Commonly, the 8-pin and 11-pin connectors include additional signals for controlling the speed of the orbiting-speaker effect. Additionally, the 8-pin or 11-pin connector may include a stereo pair, which would replace the separate audio cables required for the left- and right-audio signals. In this example, the special monaural signal would be treated as channel 1 and the stereo pair would be treated as channel 2. The other connectors that may be available for channels 1 and 2 would be disabled or unused.

In this exemplary embodiment, power from the mains 520 is supplied to the input module 501. A single, four-conductor cable connects the input module 501 to the controller 502. The four conductors carry low-Voltage, direct current power, signal common and two digital signals. The controller 502 may be a stand-alone device or integrated into a musical instrument, musical instrument controller or other piece of equipment. The controller 502 may be comprised of a device with physical controls coupled with a general purpose computing device, such as a personal computer, portable computer, tablet computer or smart phone. The mixer controller 502 and the input module 501 may be part of the same piece of equipment.

The outputs of this exemplary embodiment consist of a stereo pair of XLR jacks 511 with analog audio signals suitable to send to a master mixing console and a digital audio-signal output 510 suitable for the electronically-orbited speaker system. The digital audio-signal output 510 is eight channel, time-division-multiplexed including clock and framing signals in an LVDS format. The cables and connectors are commonly used for Ethernet 100 baseT networks.

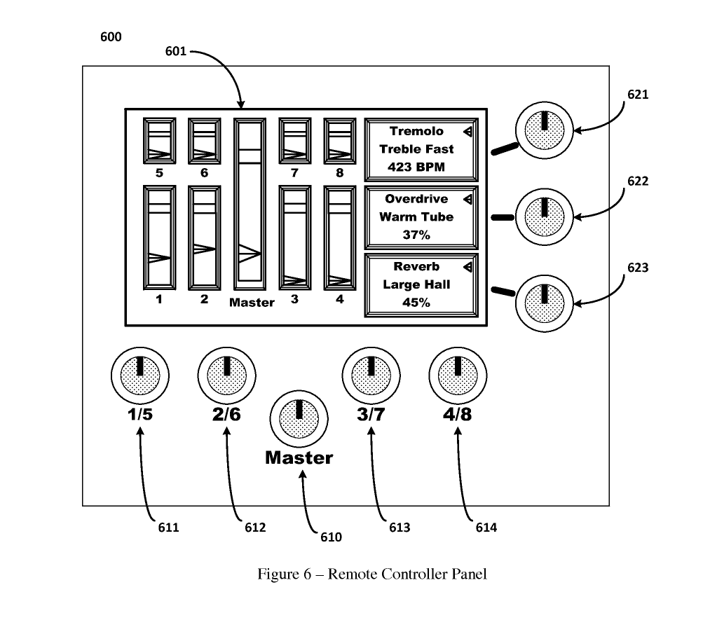

FIG. 6 depicts the control panel 600 of the remote mixer controller 502 that is an exemplary embodiment of the present invention. In this configuration, there are eight controls 610, 611, 612, 613, 614, 621, 622, 623 and one display screen 601. Each control is made up of a rotary encoder and a key switch.

When the knob of a control is turned, the encoder produces signals that are decoded by the microcontroller as turning to the left or turning to the right. The shaft of the control includes a mechanical-detent mechanism that confines the rotation of the knob to discrete steps. Each step results in one set of signals to the microcontroller, a step to the left or a step to the right. The steps are used to increase volume level or decrease volume level or to move to different menu items or selections. Rotary encoders are inexpensive, reliable and easy to interface to a microcontroller. More importantly, rotary encoders are easier for a player to grab and adjust for a number of steps with little or no visual interaction. This is the first important part of making the mixer usable during a live performance.

When the knob of a control is depressed, the key switch part of the control sends a signal to the microcontroller. The key switch signal is used for selection, and, as will be described below, is a second important part of making the complex user interface of the mixer quickly and intuitively accessible to the player. Some selections cause a parameter to toggle or alternate between two states with each depression of the key switch. Some selections are a radio button action where depressing one key switch of a bank of key switches selects the parameter associated with the one key switch. Depressing another key switch from the bank selects the parameter associated with that key switch. A third key switch action is that of incrementing a cursor in a modulo fashion. Depressing the key switch once, increments the cursor to the next position. When the last position is reached, the next depression moves the cursor to the first position.

Each control could be implemented as a rotary encoder, an optical encoder, a linear encoder, a potentiometer, up/down buttons, touch controller, touch screen, each with an integrated or associated key switch or toggle switch, or the control may be implemented with any other technology or mechanism while practicing the present invention. The control may include illumination. Rotary shaft encoders are available with a transparent shaft and one or more LEDs to illuminate the knob placed on the shaft. Illumination may be used to make the controls easier to locate on a dark stage or may be used to indicate parameters, such as active channel bank or highlighted channel. As an example, the channel volume controls may be illuminated green when the lower bank is active; except the highlighted channel is illuminated red. When the upper channel bank is active, the channel volume controls may be red; except for the highlighted channel is illuminated green. Many other colors and combinations of indication may be used.

A third important part of making the user interface more accessible is using banks of channels whereby a plurality of parameters are controlled by a limited number of controls. In the exemplary embodiment there are eight input channels in two banks controlled by four controls. Each control controls two different input channels depending on which bank is selected. This could be expanded by adding banks. Humans have four fingers on a hand and experience has shown that four controls arrayed in a row, plus one master control that is centered and physically offset from the row is easy to negotiate with little or no visual interaction. Having one control per channel, eight in the case of this exemplary embodiment, leads to having to count by feel or by looking at the labels on the controls to find the right one. Having one control for each channel is too complex and a single control for all channels requires multiple actions. The differentiation of the master control may be by displacement from the centerline of the row of controls, by a different size knob, by a different height knob, by a different shaped knob or by any other difference that is easily sensed by the user.

While using four controls plus a master to control eight, twelve, sixteen or more audio channels in banks of four is the ideal for player input, the player wants to be able to see the level setting and VU meter reading for all channels at once. At the same time, the player wants to know which channel bank is active on the controls.

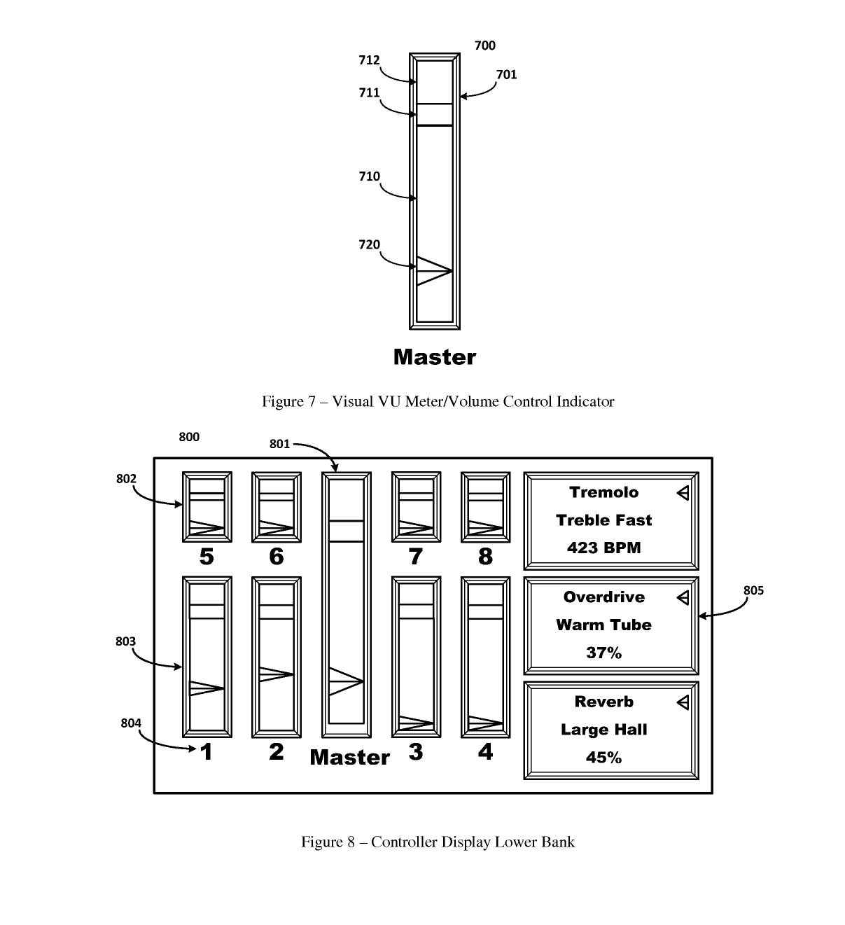

FIG. 7 details the combination VU meter and volume control that is part of the color display. The VU meter/volume indicator 700 in FIGS. 7 and 801 in FIG. 8 depicts the Master, though the details for the active bank VU meter/volume indicators 803 and inactive bank VU meter/volume indicators 802 are the same. Only the size of each type is different. The border 701 is decorative and differentiates the VU meter/volume indicator 700 from the rest of the display. The Master VU meter/volume indicator 700 indicates the audio-level setting made by the Master control 610 and the output-signal level measurement. The indicator 720 moves up the display as the Master control 610 is turned to the right. The indicator 720 moves down the display as the Master control 610 is turned to the left. This intuitively corresponds to moving the level-control slider 320 on a standard mixing board. The VU meter display is made up of a plurality of segments 710, 711, 712 that illuminate in degrees, usually from the bottom up, to indicate the measured volume units. Segment 710 may be green to indicate a safe, audio level; segment 711 may be yellow to indicate a warning level; and segment 712 may be red to indicate signal-overload condition. The segments 710, 711, 712 may be illuminated at a low level to show the boundaries of the segments and then progressively at a brighter level to indicate the audio signal level. The VU meter/volume indicator 700 may be implemented as one or more LCD, OLED, CRT or other type display or may be discrete LEDs, incandescent lamps or any other indicators.

FIG. 8 depicts an exemplary embodiment of the display 800 that is part of the controller panel 600. The Master VU meter/volume indicator 801 is always responsive to the Master control 610 and always indicates the output, volume-level setting and the output, signal-level measurement. In this case, the lower bank is active and the VU meter/volume indicator 803 for channel 1 is tall and the VU meter/volume indicator 802 for channel 5 is short. Channel 1 is part of the lower, active bank, while channel 5 is part of the upper, inactive bank. Control 611 now adjusts the volume level of channel 1. Controls 612, 613, 614 adjust the associated channels 2, 3 and 4.

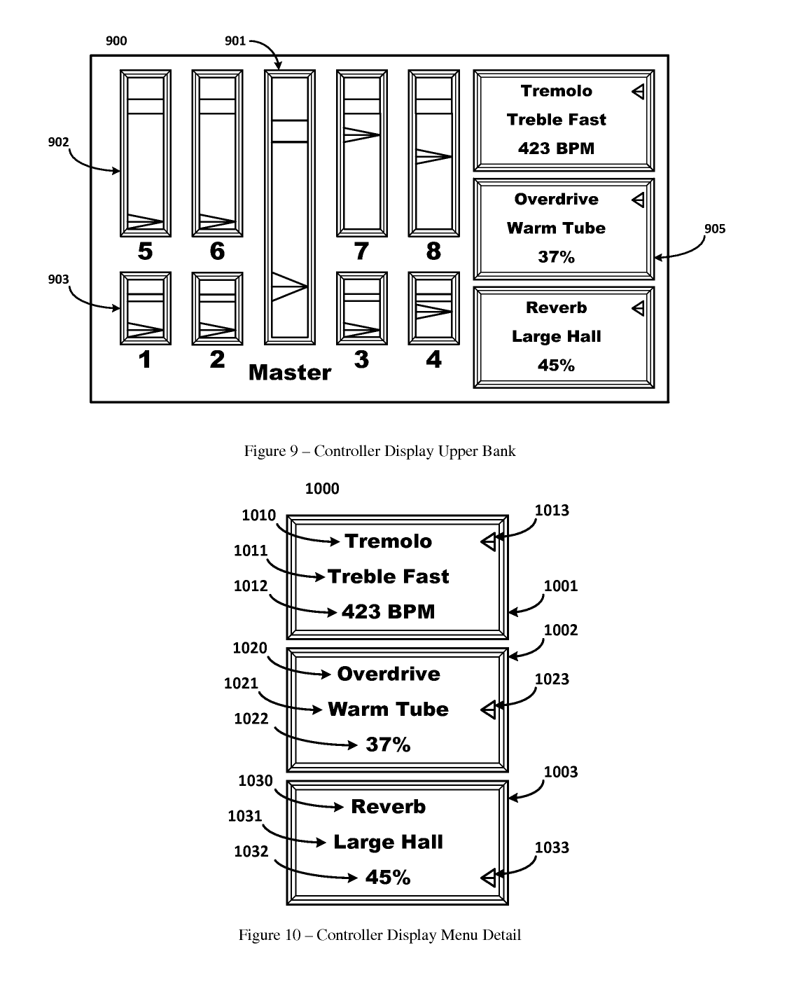

When the Master control 610 is momentarily depressed, the display 800 and function of the controls toggle between the lower bank, depicted in FIG. 8, and the display for the upper bank 900, depicted in FIG. 9. The lower bank becomes active and the VU meter/volume indicator 903 for channel 1 is short and the VU meter/volume indicator 902 for channel 5 is tall. Channel 1 is part of the lower, inactive bank, while channel 5 is part of the upper, active bank. Control 611 now adjusts the volume level of channel 5. Controls 612, 613, 614 now adjust the associated channels 6, 7 and 8. The active bank may also be indicated by changing the width, color, decoration or any other aspect of the VU meter/volume indicator. The active bank may also be indicated by changing the background color of the display. Depressing the Master control 610 for at least 1 second may access hidden menus for such items as memory configurations and system setup. The controls may operate in different modes. The memory configuration may have user assignable names, whereby the user may preconfigure all volume levels and menu settings for a song or set of songs and quickly retrieve those settings during a live performance. The Master control 610 may be implemented as two physical controls, one of which adjusts the left-output, audio-signal level and the second control adjusts the right-output, audio-signal level; while the key switches for both physical controls select the active bank.

The menus 805 are responsive to the channel controls 611, 612, 613, 614 and the selected bank. If the lower bank is active, when control 611 is depressed, the menu windows 805 for channel 1 become active, indicated by the label on channel 1 804 highlighted, such as reverse video effect and the menus and settings for channel 1 being displayed in the menu windows 805. In the case of a white channel label 804 on a blue background, the reverse video effect may be a black character on a yellow background. If one of the other channel controls 612, 613, 614 is depressed, the menus associated with the selected channel would be displayed. If channel control 3 613 were depressed, the label on channel 3 would be reverse video effect and the channel 3 menus and settings would be displayed. Subsequently, if the Master control 610 were depressed to switch banks, the label for channel 7 would be reverse video and the menus and settings for channel 7 would be displayed. Only one channel label 804 would be highlighted at a time and menus and settings for only one channel displayed at a time.

FIG. 10 depicts the menu windows 1000 in the exemplary embodiment. These menu windows display the selections and settings for the highlighted channel. The top menu 1001 displays the selections and parameters for the first sound effect in the audio chain between input and the output. The example here shows that a tremolo effect has been selected 1010 and that for the fast tremolo speed for the treble channel 1011 the rate setting 1012 is 423 beats per minute. The menu cursor 1013 is pointing at the tremolo selection. If the menu control 621 is rotated, other sound-effect selections appear on the display and are selected as soon as they appear. No entry button is needed. If the menu control 621 is depressed, the menu cursor 1013 moves to the middle line 1011. Rotating the menu control 621 now selects different parameters 1011 for the sound effect displayed 1010. Depressing the menu control 621 again moves the menu cursor 1013 to the bottom line 1012 where the value for the parameter displayed at 1011 is set. Depressing the menu control 621 again moves the menu cursor 1013 to the top line 1010. The other menu windows 1002, 1003 operate in a similar fashion for the second and third sound effects in the audio chain for the highlighted channel.

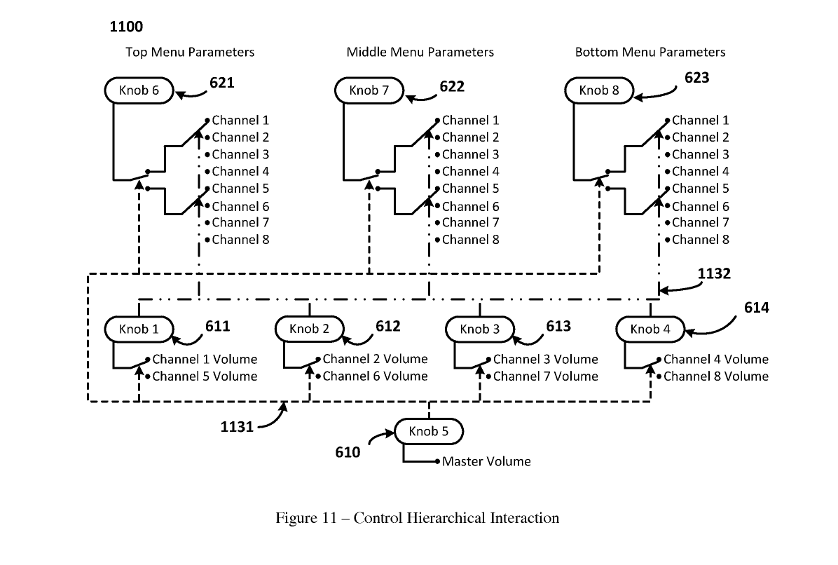

FIG. 11 depicts the logic 1100 of the hierarchical interaction between the controls 610, 611, 612, 613, 614, 621, 622, 623. The results of these interactions appear on the display 601. The Master control 610 always adjusts the output audio level when turned and always toggles between banks when depressed. The dashed line 1131 indicates the link between the key switch of the Master control 601 and the function of the remaining controls 611, 612, 613, 614, 621, 622, 623 where the functions of each control switch between the lower bank and the upper bank. When the lower bank is active, the channel volume controls 611, 612, 613, 614 adjust the volume level of channels 1, 2, 3 and 4; and the menu controls 621, 622, 623 select parameters or set values for the highlighted channel from the set 1, 2, 3 and 4. When the Master control 610 is depressed once the upper bank becomes active, the channel volume controls 611, 612, 613, 614 adjust the volume level of channels 5, 6, 7 and 8; and the menu controls 621, 622, 623 select parameters or set values for the highlighted channel from the set 1, 2, 3 and 4. If the Master control 610 is depressed again, the active bank switches back to the lower bank.

The dash-dot-dot line 1132 indicates the link between the key switches of the channel volume controls 611, 612, 613, 614 and the function of the menu controls 621, 622, 623. When any one of the channel volume controls 611, 612, 613, 614 is depressed, the highlighted channel changes to the channel in the active bank that is associated with that control. For example, if channel volume control 613 were depressed when the lower bank is active, the highlight would shift to channel 3. If channel volume control 613 were depressed when the upper bank is active, the highlight would shift to channel 7. Similarly, if the highlight is on channel 3 and the Master control 610 is depressed, the highlight will shift to channel 7. The menu items that are displayed are associated with the highlighted channel. Whenever the highlighted channel is shifted, as described above, the menu items for the new highlighted channel are displayed. The menu controls 621, 622, 623 make selections and settings as described in FIG. 10.

By using a hierarchical control structure 1100 with appropriate switching function (toggle, radio button, modulo incrementing) allows four volume controls and one Master control to adjust eight, twelve or more audio channels with easy-to-master finger control with limited or no visual interaction, and to display and immediately adjust menu items for individual audio channels or stereo pairs without additional menu-tree traverse and no enter key required for activation of menu changes.

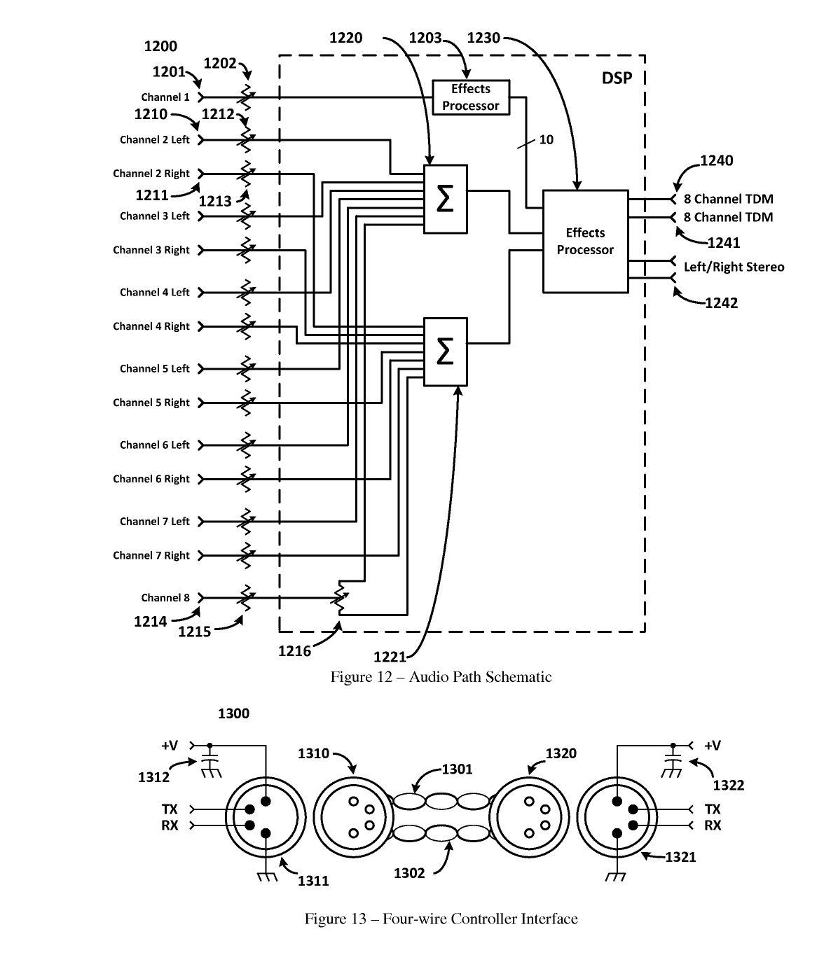

FIG. 12 is a schematic of an exemplary and simplified audio path 1200 through the mixer input module 501. As the audio paths in this exemplary embodiment are largely defined by DSP software, the paths may be reconfigured in more complex ways with a plurality of effects processing blocks 1203, 1230, and a plurality of summation nodes 1220, 1221 before and optionally after the effects processors 1203, 1230.

Channel 1 input 1201 exemplifies a monaural audio channel input that undergoes special effects processing 1203 in addition to the effects processing 1230 that applies to all channels. An audio signal from an instrument or other sound source is introduced at connector 1201 and the signal level adjusted by volume control 1202. The signal is coupled to the effects processor 1203 where the signal is divided ten ways and processed to produce an orbiting speaker effect with celeste. The ten signals are coupled to the global effects processor 1230 where further sound effects, such as spatial reverberation, are added. The result is four audio channels of an emulated treble horn, four audio channels of an emulated bass rotor, two channels of subwoofer and a left/right stereo pair to send to the master mixing console. The treble horn and bass rotor signals are routed to the orbital speaker cabinets via the eight channel, time-division-multiplexed digital outputs 1240. The subwoofer signals are routed to the subwoofer cabinet via the other TDM digital output 1241. The orbiting speaker effect is described in detail in the incorporated patent applications referenced in [0021].

Channel 2 is intended for a stereo instrument and is comprised of two inputs, one for the left signal 1210 with volume control 1212 and one for the right signal 1211 with volume control 1213. The left and right signals for all the stereo channels are combined by the summing nodes 1220, 1221 and coupled to the global effects processor 1230. There is left and right signals are divided, filtered, levels adjusted and coupled to the outputs 1240, 1241, 1242 in a manner that produces a stereo sound field. Optionally, the signals from one or more stereo channels are coupled to an orbiting-speaker effects processor (not shown) in a manner similar to the description for the effects processor 1203.

Channel 8 input 1214 exemplifies a monaural channel. The signal introduced at 1214 is coupled to volume control 1215 and further coupled to pan control 1216. The pan control 1216 sends the signal to the left summation node 1220 or the right summation node 1221 or both. In a similar fashion to the stereo channels, the signal is coupled to the outputs 1240, 1241, 1242.

FIG. 13 is a schematic of the four-wire connection between the input module 501 and the controller 502 that carries two single-ended digital signals and power. The connector 1311 is on the input module, connector 1321 is on the controller and connectors 1310, 1320 are on the ends of the cable that interconnects the two pieces of equipment. It is advantageous for each of the digital signals to be carried over a twisted pair of wires 1301, 1302; the signal wire to be twisted with a common or chassis ground wire. The separate, twisted pairs provide a shielding effect that reduces crosstalk between the signals. It is also advantageous to use a cable with only two twisted pairs of wire as this is a common and inexpensive alternative to cables with higher wire count. One digital signal is twisted with the common wire, as is standard practice. The other digital signal is twisted with the power wire. The power wire is bypassed to common with a capacitor 1312 at the input module and capacitor 1322 at the controller. This bypassing with capacitors at each end makes the power wire look like a common wire for AC signals. Crosstalk only occurs at higher AC frequencies, so this solution effectively provides two common wires for the digital signals.

Those of skill would appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components, blocks, modules, circuits, and steps above have been described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the exemplary embodiments disclosed herein may be embodied directly in hardware, in a software module executed by a processor, or in a combination of the two. A software module may reside in Random Access Memory (RAM), flash memory, Read Only Memory (ROM), Electrically Programmable ROM (EEPROM), Electrically Erasable Programmable ROM (EEPROM), registers, hard disk, a removable disk, a CD, DVD, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in an electronically orbited speaker. In the alternative, the processor and the storage medium may reside as discrete components in an electronically-orbited speaker.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, Flash, CD, DVD or other optical-disk storage, magnetic-disk storage or other magnetic-storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What I claim is:

1. An apparatus for controlling audio signal mixing, comprising:
a master control that adjusts the mixed audio signal level and selects a bank of active channels; and
a plurality of channel volume controls that each adjust the audio signal level of one active channel and select the highlighted channel; and
at least one menu control that selects menu items or values and increments the position of the menu cursor.

2. The apparatus of claim 1, wherein the apparatus further comprises a continuously visible volume control setting indicator for the master channel; and
a continuously visible VU meter for the master channel; and
a continuously visible volume control setting indicator for each audio channel; and
a continuously visible VU meter for each audio channel; and
a continuously visible menu that displays at least one parameter setting or value for the active and highlighted audio channel.

3. The apparatus of claim 1, wherein the number of audio channels is an integer multiple greater than one of the number of channel volume controls.

4. The apparatus of claim 1, wherein the number of channel volume controls is greater than two and fewer than seven.

5. The apparatus of claim 1, wherein the number of channel volume controls is four.

6. The apparatus of claim 1, wherein the apparatus further comprises a display screen that displays the master-channel volume-control setting, the master-channel VU meter, the audio-channel volume-control setting indicators, the audio-channel VU meters and the at least one menu.

7. The apparatus of claim 1, wherein the active bank is indicated by one or more of the height, width, color, shape or decoration of the associated VU meters or volume-control indicators, or by changing the background color of the display.

8. The apparatus of claim 1, wherein at least one of the audio channels includes signal paths for a plurality of audio signals.

9. The apparatus of claim 1, wherein the selection by the menu control is immediately applied without further user action.

10. The apparatus of claim 1, wherein the differentiation of the master control may be by displacement from the centerline of a row of controls, by a different size knob, by a different height knob, by a different shaped knob or by any other difference that is easily sensed by the user.

11. The apparatus of claim 1, wherein depression of the master control for more than 1 second accesses hidden menus.

12. The apparatus of claim 1, wherein the controller is remote from the audio mixing module.

13. The apparatus of claim 1, wherein the menus include parameters for controlling an orbital-speaker effect.

14. The apparatus of claim 1, wherein the controls are illuminated.

15. The apparatus of claim 1, wherein the controller is part of a musical instrument, musical instrument controller or other piece of equipment.

16. The apparatus of claim 1, wherein the controller and the audio mixing circuitry are part of the same piece of equipment.

17. A method for controlling audio signal mixing, comprising:
a master control that adjusts the mixed audio-signal level and selects a bank of active channels; and
a plurality of channel volume controls that each adjust the audio-signal level of one active channel and select the highlighted channel; and
at least one menu control that selects menu items or values and increments the position of the menu cursor.

18. The method of claim 17, wherein the method further comprises a continuously visible volume control setting indicator for the master channel; and
a continuously visible VU meter for the master channel; and
a continuously visible volume control setting indicator for each audio channel; and
a continuously visible VU meter for each audio channel; and
a continuously visible menu that displays at least one parameter setting or value for the active and highlighted audio channel.

19. A computer program product, comprising:
a computer-readable medium comprising:
code for controlling audio signal mixing, comprising:
receiving a signal from a master control and adjusting the mixed audio-signal level and selecting a bank of active channels; and
receiving signals from a plurality of channel volume controls and adjusting the audio signal level of one active channel and selecting the highlighted channel; and
receiving a signal from at least one menu control and selecting menu items or values and incrementing the position of the menu cursor.

20. The computer program product of claim 19, wherein the computer program product further comprises controlling a continuously visible volume control setting indicator for the master channel; and
controlling a continuously visible VU meter for the master channel; and
controlling a continuously visible volume control setting indicator for each audio channel; and
controlling a continuously visible VU meter for each audio channel; and
controlling a continuously visible menu that displays at least one parameter setting or value for the active and highlighted audio channel.
